(19) United States
(12) Patent Application Publication
(10) Pub. No.: US 2007/0070720 A1
(43) Pub. Date: Mar. 29, 2007

(54) Voltage generator for use in semiconductor device

(75) Inventors: Kang-Seol Lee, Kyoungki-do (KR); Jae-Jin Lee, Kyoungki-do (KR)

Correspondence Address: MCDERMOTT WILL & EMERY LLP, 600 13TH STREET, N.W., WASHINGTON, DC, 20005-3096, US

(73) Assignee: HYNIX SEMICONDUCTOR INC.

(21) Appl. No.: 11/478,192

(22) Filed: Jun. 30, 2006

(30) Foreign Application Priority Data
Sep. 29, 2005 (KR) 2005-0090899
Dec. 6, 2005 (KR) 2005-0118143

(51) Int. Cl. G11C 5/14

(52) U.S. Cl. 365/189.09

(57) ABSTRACT

A voltage generator for use in a semiconductor memory device includes an output voltage controller for generating a bias voltage using a reference voltage of which a voltage level is half of a core voltage level. Pull-up/pull-down driving signals are output by generating a voltage which is higher or lower than the reference voltage by a threshold voltage. An output driver generates a bit line precharge voltage in response to the pull-up driving signal or the pull-down driving signal. Drive controllers interrupt off-leakage current of the output driver. One drive controller is disposed between the output driver and a core voltage terminal and another drive controller is between the output driver and a ground voltage terminal.

### FIELD OF THE INVENTION

The present invention relates to a voltage generator for use in a semiconductor memory device; and, more particularly, to a voltage generator capable of stably generating a bit line precharge voltage or a cell plate voltage in a low power voltage state, and minimizing a standby current as well.

### DESCRIPTION OF RELATED ART

In general, there are many cases in which a semiconductor memory device has low drivability due to various conditions for process variations. Low drivability may cause the semiconductor memory device to erroneously operate because the low drivability leads to a great change in an internal voltage.

Since the process variation becomes more serious as the semiconductor memory device is more highly integrated, the gradual decrease of a core voltage makes the drivability of an output driver in a voltage generation circuit for generating a bit line precharge voltage VBLP or a cell plate voltage VCP decrease also.

FIG. 1 is a circuit diagram of a conventional bit line precharge voltage VBLP generator.

The conventional bit line precharge voltage generator includes an output voltage controller 10 and an output driver 20. The output voltage controller 10 is provided with a voltage divider 11, a bias voltage generator 12, and a gate voltage generator 13.

The voltage divider 11 divides a core voltage VCORE to generate a half core voltage, i.e., ½×VCORE, which becomes a reference voltage for a bit line precharge voltage VBLP or a cell plate voltage VCP. The voltage divider 11 is configured with PMOS transistors P1 and P2 and resistors R1 and R2 which are connected to each other in series between a core voltage VCORE terminal and a ground voltage VSS terminal. That is, the voltage divider 11 is implemented using a self bias diode resistor and a line resistor to thereby generate a reference voltage REF.

If an external power voltage is supplied, the reference voltage REF is generated using the voltage divider 11 as illustrated in FIG. 1. However, if the power voltage is internally generated, the reference voltage REF may be generated through another reference voltage generator.

The bias voltage generator 12 generates p-bias and n-bias voltages PBIAS and NBIAS using the reference voltage REF. The bias voltage generator 12 is configured with a plurality of PMOS transistors P3 to P6 and a plurality of NMOS transistors N1 to N6.

The PMOS transistor P3 and the NMOS transistors N1 and N3 are connected in series between the core voltage VCORE terminal and the ground voltage VSS terminal, which enables a constant current to flow to the ground voltage VSS terminal. The reference voltage REF is applied to a gate of the PMOS transistor P3, and each of the NMOS transistors N1 and N3 is configured such that a gate and a drain are commonly connected to each other, i.e., diode-connected.

The PMOS transistor P4 and the NMOS transistors N2 and N4 are connected in series between the core voltage VCORE terminal and the ground voltage VSS terminal, to form a current mirror structure, which enables a constant current to flow to the core voltage VCORE terminal. The PMOS transistor P4 is configured such that a gate and a drain are commonly connected to each other. In addition, gates of the NMOS transistors N2 and N4 are coupled to the respective gates of the NMOS transistors N1 and N3 in current mirror fashion so that a mirroring current equal to the current flowing through the NMOS transistors N1 and N3 flows through the NMOS transistors N2 and N4.

The PMOS transistor P5 is connected between the core voltage VCORE terminal and an NMOS transistor N7, and a gate of a PMOS transistor P5 is coupled to the gate of the PMOS transistor P4 in current mirror fashion. The PMOS transistor P6 is connected between the core voltage VCORE terminal and an NMOS transistor N8, and the p-bias voltage PBIAS is applied to a gate thereof. The NMOS transistor N5 is connected between the ground voltage VSS terminal and a PMOS transistor P7, and the n-bias voltage NBIAS is applied to a gate thereof. The NMOS transistor N6 is connected between the ground voltage VSS terminal and a PMOS transistor P8, and the n-bias voltage NBIAS is also applied to a gate thereof.

The gate voltage generator 13 is configured with NMOS transistors N7 and N8 and PMOS transistors P7 and P8, which constitute current mirror structures, respectively. Herein, an n-gate voltage NGATE is commonly applied to gates of the NMOS transistors N7 and N8, and a p-gate voltage PGATE is commonly applied to gates of the PMOS transistors P7 and P8. The gate voltage generator 13 generates the n-gate voltage NGATE which is higher than the reference voltage REF by the threshold voltage of the NMOS transistor N7, and the p-gate voltage PGATE which is lower than the reference voltage REF by the threshold voltage of the PMOS transistor P7.

The output driver 20 is configured with a PMOS transistor P9 and an NMOS transistor N9, which are connected in series between the core voltage VCORE terminal and the ground voltage VSS terminal. A pull-up driving signal PDRV is applied to a gate of the PMOS transistor P9, and a pull-down driving signal NDRV is applied to a gate of the NMOS transistor N9. Through a common drain of the PMOS and NMOS transistors P9 and N9, the bit line precharge voltage VBLP is output.

The described conventional voltage generator may prevent the drivability from being reduced even if an internal power voltage becomes low in virtue of the transistors P9 and N9. In order to increase the drivability at an end terminal of the output driver 20, the conventional voltage generator employs the PMOS and NMOS transistors P9 and N9 having a low threshold voltage in the output driver 20. However, while active and read/write operations may be enhanced because of good drivability, an undesirably large amount of off-leakage current flows during a precharge state.

That is, the threshold voltage of the PMOS transistor P9 is reduced by a small amount from a target value, a precharge current, i.e., a standby current, is undesirably generated due to the large amount of off-leakage current. Accordingly, the memory device will be out of specification. In particular, a fatal error may be incurred in devices in which the standby current is a very important factor, e.g., a low power device, a mobile device, and the like.

If the threshold voltages of the PMOS transistor P9 and the NMOS transistor N9 are lowered in order to secure an operational range of the output driver, to thereby improve the drivability characteristic, there is a drawback in that tremendous current loss occurs due to increased standby current.

### SUMMARY OF THE INVENTION

It is, therefore, an object of the present invention to provide a voltage generator having a drive controller for source degeneration, capable of stably supplying a bit line precharge voltage or a cell plate voltage in a low power voltage state, and minimizing a standby current IDD2P as well, wherein the voltage generator employs PMOS and NMOS transistors with low threshold voltages in an output driver.

In accordance with an aspect of the present invention, there is provided a voltage generator including an output voltage controller for generating a bias voltage using a reference voltage of which a voltage level is half of a core voltage level, and outputting pull-up/pull-down driving signals by generating a voltage which is higher or lower than the reference voltage by a threshold voltage; an output driver for generating a bit line precharge voltage in response to the pull-up driving signal or the pull-down driving signal; and drive controllers for interrupting an off-leakage current of the output driver, wherein one drive controller is disposed between the output driver and a core voltage terminal and another drive controller is between the output driver and a ground voltage terminal.

### BRIEF DESCRIPTION OF THE DRAWINGS

The above and other objects and features of the present invention will become better understood with respect to the following description of the preferred embodiments given in conjunction with the accompanying drawings, in which:

FIG. 1 is a circuit diagram showing a conventional voltage generator;

FIG. 2 is a circuit diagram showing a voltage generator in accordance with one embodiment of the present invention;

FIG. 3 is a circuit diagram describing a voltage generator in accordance with another embodiment of the present invention; and

FIGS. 4A to 4C are waveform diagrams depicting an operation of the voltage generator according to the present invention.

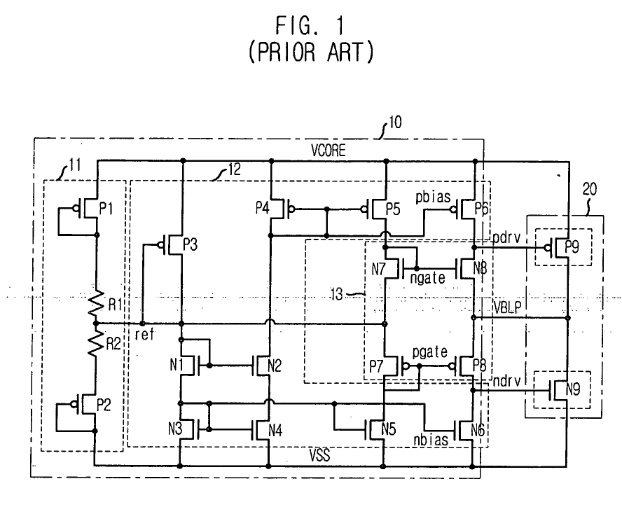

### DETAILED DESCRIPTION OF THE INVENTION

A semiconductor memory device having a voltage generator in accordance with exemplary embodiments of the present invention will be described in detail with reference to the accompanying drawings.

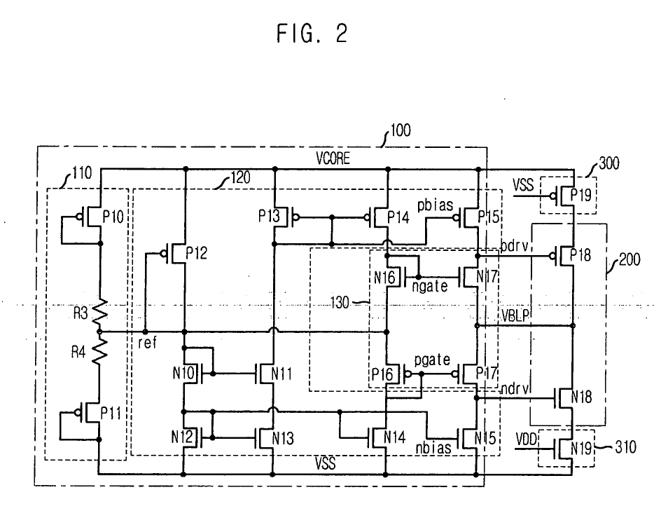

FIG. 2 is a circuit diagram of a voltage generator in accordance with one embodiment of the present invention.

Referring to FIG. 2, the voltage generator of the present invention includes an output voltage controller 100, an output driver 200, and drive controllers 300 and 310. The output voltage controller 100 is provided with a voltage divider 110, a bias voltage generator 120, and a gate voltage generator 130.

The voltage divider 110 divides a core voltage VCORE to generate half of the core voltage, i.e., ½×VCORE, which becomes a reference voltage for a bit line precharge voltage VBLP or a cell plate voltage VCP. The voltage divider 110 is configured with a PMOS transistor P10 and P11 and a resistor R3 and R4 which are connected to each other in series between a core voltage VCORE terminal and a ground voltage VSS terminal. The voltage divider 110 is implemented using a self bias diode resistor and a line resistor to thereby generate a reference voltage REF.

If an external power voltage is inputted, the reference voltage REF is generated using the voltage divider 11 as illustrated in FIG. 2. However, if the power voltage is internally generated, the reference voltage REF may be generated through another reference voltage generator.

The bias voltage generator 120 generates p-bias and n-bias voltages PBIAS and NBIAS using the reference voltage REF. The bias voltage generator 120 is configured with a plurality of PMOS transistors P12 to P15 and a plurality of NMOS transistors N10 to N15.

The PMOS transistor P12 and the NMOS transistors N10 and N12 are connected in series between the core voltage VCORE terminal and the ground voltage VSS terminal, which enables a constant current to flow to the ground voltage VSS terminal. The reference voltage REF is applied to a gate of the PMOS transistor P12, and each of the NMOS transistors N10 and N12 is configured such that a gate and a drain are commonly connected to each other, i.e., diode-connected.

The PMOS transistor P13 and the NMOS transistors N11 and N13 are connected in series between the core voltage VCORE terminal and the ground voltage VSS terminal, to form a current mirror structure, which enables a constant current to flow to the core voltage VCORE terminal. The PMOS transistor P13 is configured such that a gate and a drain are commonly connected to each other. Gates of the NMOS transistors N11 and N13 are coupled to the respective gates of the NMOS transistors N10 and N12 in current mirror fashion so that a mirroring current equal to the current flowing through the NMOS transistors N10 and N12 flows through the NMOS transistors N11 and N13.

The PMOS transistor P14 is connected between the core voltage VCORE terminal and an NMOS transistor N16, and a gate of a PMOS transistor P14 is coupled to the gate of the PMOS transistor P13 in current mirror fashion. The PMOS transistor P15 is connected between the core voltage VCORE terminal and an NMOS transistor N17, and the p-bias voltage PBIAS is applied to a gate thereof. The NMOS transistor N14 is connected between the ground voltage VSS terminal and a PMOS transistor P16, and the n-bias voltage NBIAS is applied to a gate thereof. The NMOS transistor N15 is connected between the ground voltage VSS terminal and a PMOS transistor P17, and the n-bias voltage NBIAS is also applied to a gate thereof.

The gate voltage generator 130 is configured with NMOS transistors N16 and N17 and PMOS transistors P16 and P17, which constitute current mirror structures, respectively. An n-gate voltage NGATE is commonly applied to gates of the NMOS transistors N16 and N17, and a p-gate voltage PGATE is commonly applied to gates of the PMOS transistors P16 and P17. The gate voltage generator 130 generates the n-gate voltage NGATE which is higher than the reference voltage REF by the threshold voltage of the NMOS transistor N16, and the p-gate voltage PGATE which is lower than the reference voltage REF by the threshold voltage of the PMOS transistor P16.

The output driver 200 is configured with a PMOS transistor P18 and an NMOS transistor N18 which are connected in series between the core voltage VCORE terminal and the ground voltage VSS terminal. A pull-up driving signal PDRV is applied to a gate of the PMOS transistor P18, and a pull-down driving signal NDRV is applied to a gate of the NMOS transistor N18. Through a common drain of the PMOS and NMOS transistors P18 and N18, the bit line precharge voltage VBLP is outputted.

The drive controller 300 includes a PMOS transistor P19 connected between the core voltage VCORE terminal and the PMOS transistor P18, wherein the ground voltage VSS is applied to the gate thereof. The drive controller 310 includes a NMOS transistor N19 connected between the ground voltage VSS terminal and the NMOS transistor N18, wherein a power voltage VDD is applied to the gate thereof.

The voltage generator of the present invention employs the PMOS and NMOS transistors P18 and N18 having a low threshold voltage in the output driver 200. Therefore, even if the internal power voltage is low, it is possible to prevent the drivability from being lowered and secure an operational range of the output driver 200.

The inventive voltage generator further includes the drive controllers 300 and 310 configured with the normal PMOS and NMOS transistors P19 and N19 at both ends of the output driver 200 for source degeneration. Accordingly, the voltage generator can utilize the drivability of the output driver 200 in a normal mode, and further can control the leakage current path of the PMOS and NMOS transistors P18 and N18 having a low threshold voltage using the normal PMOS and NMOS transistors P19 and N19.

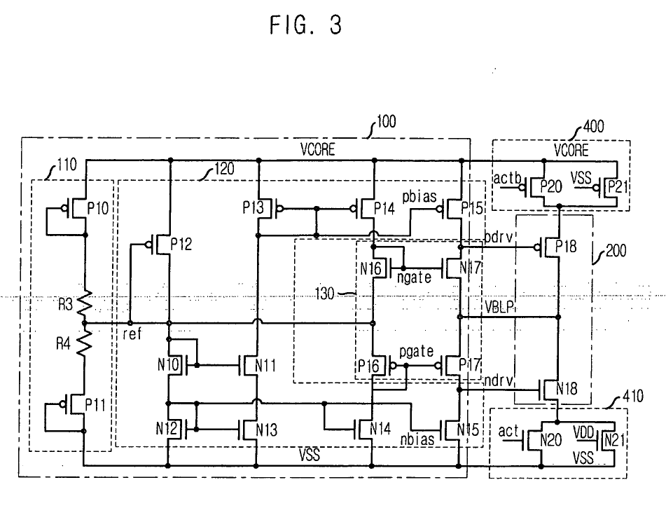

FIG. 3 is a circuit diagram of a voltage generator in accordance with another embodiment of the present invention.

Referring to FIG. 3, the voltage generator includes an output voltage controller 100, an output driver 200, and drive controllers 400 and 410. The output voltage controller 100 is provided with a voltage divider 110, a bias voltage generator 120, and a gate voltage generator 130.

The output voltage controller 100 and the output driver 200 in the voltage generator in accordance with this embodiment are identical to those of FIG. 2, but the drive controllers 400 and 410 are different from those of FIG. 2. Thus, further description for the output voltage controller 100 and the output driver 200 will be omitted.

The drive controller 400 includes PMOS transistors P20 and P21, which are connected to each other in parallel, wherein the PMOS transistors P20 and P21 are connected between a core voltage VCORE terminal and a PMOS transistor P18. An active bar signal ACTB is applied to a gate of the PMOS transistor P20 and a ground voltage VSS is applied to a gate of the PMOS transistor P21.

The drive controller 410 includes NMOS transistors N20 and N21, which are connected to each other in parallel, wherein the NMOS transistors N20 and N21 are connected between a ground voltage VSS terminal and an NMOS transistor N18. An active signal ACT is applied to a gate of the NMOS transistor N20 and a power voltage VDD is applied to a gate of the NMOS transistor N21.

The voltage generator of another embodiment further includes the normal PMOS and NMOS transistors P21 and N21 at both ends of the output driver 200 for source degeneration. Accordingly, the voltage generator can utilizes the drivability of the output driver 200 in a normal mode, and can control a leakage current path of the PMOS and NMOS transistors P18 and N18 having a low threshold voltage using the normal PMOS and NMOS transistors P21 and N21.

Furthermore, the present invention utilizes the normal PMOS transistor P21 and the NMOS transistor N21 in an active mode or standby mode, respectively, under the control of the active signal ACT indicating the operational mode. Thus, if it is required to apply much more current, a large amount of current can be supplied to the output driver 200 by means of the drive controllers 400 and 410. On the contrary, if there is no need to apply much more current, the driving control unit 400 and 410 is turned off so that only the output driver 200 is used.

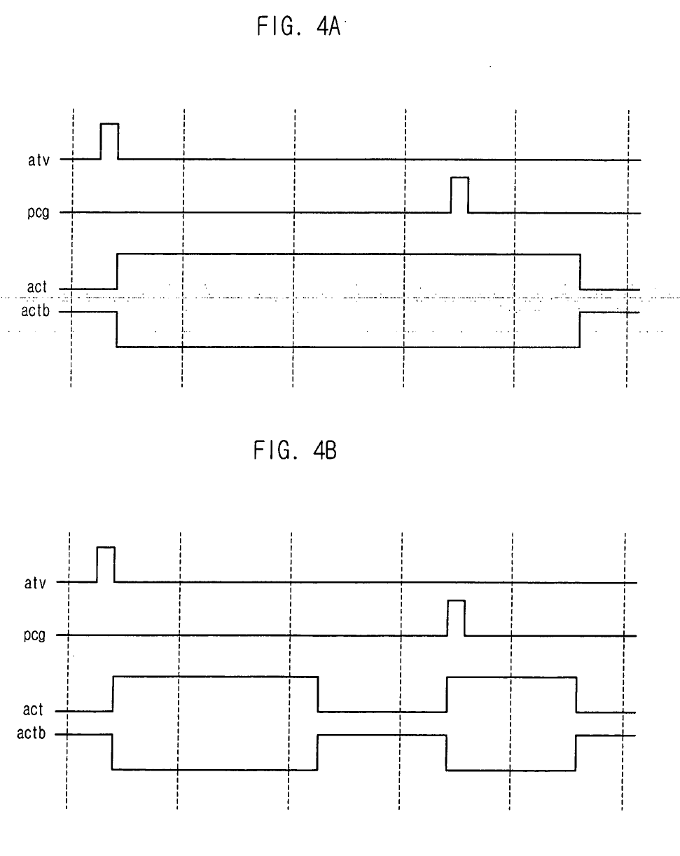

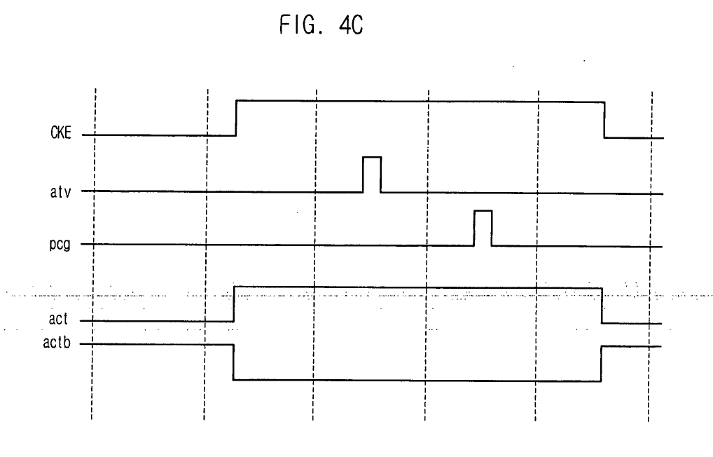

FIGS. 4A to 4C are waveform diagrams setting forth an operation of the voltage generator according to the present invention.

Referring to FIG. 4A, the active signal ACT is activated in synchronization with an activation point of an active command ATV.

The active signal ACT becomes logic high level in response to the active command ATV in the active mode. At this time, the active bar signal ACTB is activated to be logic low level. Accordingly, the NMOS and PMOS transistors N20 and P20 are turned on. At a predetermined time after a precharge signal PCG is activated in a precharge mode, the active signal ACT and the active bar signal ACTB transition to logic low and high levels, respectively. Therefore, the NMOS and PMOS transistors N20 and P20 are turned off.

Referring to FIG. 4B, the active signal ACT is activated in synchronization with the activation points of the active command ATV and the precharge signal PCG.

The active signal ACT becomes high in response to the active command ATV in the active mode. At this time, the active bar signal ACTB is activated to be logic low level. Accordingly, the NMOS and PMOS transistors N20 and P20 are turned on. The active signal ACT becomes logic low after the active command ATV is delayed for a predetermined delay time from the activation point of the precharge signal PCG, and the active bar signal ACTB is transited to logic high level. Therefore, the NMOS and PMOS transistors N20 and P20 are turned off.

Thereafter, when the precharge signal PCG is activated in the precharge mode, the active signal ACT and the active bar signal ACTB transition to logic high and low, respectively. Accordingly, the NMOS and PMOS transistors N20 and P20 are turned on. At a predetermined delay time after the precharge signal PCG is activated, the active signal ACT and the active bar signal ACTB transition to logic low and high, respectively. Therefore, the NMOS and PMOS transistors N20 and P20 are turned off.

Referring to FIG. 4C, it is understood from the waveform diagrams that the active signal ACT is activated while a clock enable signal CKE is activated.

In a non-power down mode that the clock enable signal CKE is activated, the active signal ACT becomes logic high level, and the active bar signal is activated to logic low level. Accordingly, the NMOS and PMOS transistors N20 and P20 are turned on. Thereafter, when entering the power down mode in which the clock enable signal CKE is deactivated, the active signal ACT becomes logic low level and the active bar signal ACTB transitions to logic high level. Thus, the NMOS and PMOS transistors N20 and P20 are turned off.

As described above, in accordance with the present invention, since there are employed the PMOS and NMOS transistors with low threshold voltages in the output driver and the drive controller at both ends of the output driver to implement an inventive structure adaptive for source degeneration, it is possible to stably drive the output driver to generate the bit line precharge voltage or the cell plate voltage in low power voltage state, and minimize the standby current, e.g., IDD2P, IDD2N, IDD3P, and IDD6 as well. Therefore, this structure effectively enhances the reliability of the device.

The present application contains subject matter related to the Korean patent application Nos. KR 10-2005-90899 and KR 10-2005-118143, filed in the Korean Patent Office on Sep. 29, 2005 and Dec. 6, 2005, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A semiconductor memory device, comprising:
an output voltage controller for generating a bias voltage using a reference voltage level that is half of a core voltage level, and outputting pull-up/pull-down driving signals by generating a voltage which is higher or lower than the reference voltage by a threshold voltage;
an output driver for generating a bit line precharge voltage in response to the pull-up driving signal or the pull-down driving signal; and
drive controllers for interrupting an off-leakage current of the output driver, a first one of said drive controllers coupled between the output driver and a core voltage terminal and a second one of said drive controllers coupled between the output driver and a ground voltage terminal.

2. The semiconductor memory device of claim 1, wherein the drive controller comprises a transistor for source degeneration for the current of the output driver.

3. The semiconductor memory device of claim 1, wherein the drive controller comprises:
a first transistor connected between the core voltage terminal and the output driver, wherein the ground voltage is applied to a gate thereof; and
a second transistor connected between the ground voltage terminal and the output driver, wherein a power voltage is applied to a gate thereof.

4. The semiconductor memory device of claim 3, wherein the first transistor comprises a first PMOS transistor.

5. The semiconductor memory device of claim 3, wherein the second transistor comprises a first NMOS transistor.

6. The semiconductor memory device of claim 1, wherein the output driver operates in a normal mode and a drive controller operates in a standby mode so as to interrupt an off-leakage current path of the output driver.

7. The semiconductor memory device of claim 1, further comprising a voltage generator drive control unit for enhancing current drivability of the output driver in an active operation of a predetermined command signal.

8. The semiconductor memory device of claim 7, wherein the drive control unit comprises:
a first transistor connected between the core voltage terminal and the output driver, wherein an active bar signal is applied to a gate thereof; and
a second transistor connected between the ground voltage terminal and the output driver, wherein an active signal is applied to a gate thereof.

9. The semiconductor memory device of claim 8, wherein the first transistor comprises a PMOS transistor.

10. The semiconductor memory device of claim 8, wherein the second transistor comprises a NMOS transistor.

11. The semiconductor memory device of claim 7, wherein the drive control unit is turned on in an active mode to improve the current drivability of the output driver, and is turned off in a standby mode.

12. The semiconductor memory device of claim 7, wherein the drive control unit is turned on when an active signal is activated in an active mode, and is turned off at a predetermined delay time after a precharge signal is activated in a precharge mode.

13. The semiconductor memory device of claim, 7, wherein the drive control unit is turned on when an active signal is activated in an active mode and turned off after a predetermined delay time, the drive control unit being turned on when a precharge signal is activated in a precharge operation and being turned off in at a predetermined delay time thereafter.

14. The semiconductor memory device of claim 7, wherein the drive control unit is turned on during an activation period of a clock enable signal, and is turned off during a deactivation period of the clock enable signal in a power down mode.

15. The semiconductor memory device of claim 7, wherein the output driver and the drive controller operate in a normal mode and in a standby mode, respectively, and the drive control unit operates in an active mode.
